(19) United States
(12) Patent Application Publication
(10) Pub. No.: US 2026/0126997 A1
(43) Pub. Date: May 7, 2026

(54) INFORMATION PROCESSING DEVICE, SIMULATED ANNEALING DEVICE, METHOD, AND PROGRAM

(71) Applicant: NEC Corporation, Tokyo (JP)

(72) Inventor: Takuya ARAKI, Tokyo (JP)

(73) Assignee: NEC Corporation, Tokyo (JP)

(21) Appl. No.: 19/357,472

(22) Filed: Oct. 14, 2025

(30) Foreign Application Priority Data
Nov. 7, 2024 (JP) 2024-194796

(51) Int. Cl. G06F 9/30; G06F 17/18

(52) U.S. Cl. CPC G06F 9/3001; G06F 17/18

(57) ABSTRACT

A constraint simplification unit simplifies a plurality of constraints that are each expressed as a comparison between a weighted sum of binary variables with integer values and an integer value, by deleting one of the plurality of constraints or deleting a number of binary variables used in any of the plurality of constraints.

### CROSS-REFERENCE TO RELATED APPLICATIONS

This application is based upon and claims the benefit of priority from the prior Japanese Patent Application No. 2024-194796, filed Nov. 7, 2024, the entire contents of which are incorporated herein by reference.

### BACKGROUND OF THE INVENTION

The present disclosure relates to an information processing device, a simulated annealing device, a method, and a program that perform processing for simplifying given constraints.

Research is being conducted on quantum computers capable of rapidly solving combinatorial optimization problems using quantum annealing methods. For combinatorial optimization problems represented by an Ising model, a quantum computer uses quantum superposition to search for a state that minimizes an energy function corresponding to the objective function of the combinatorial optimization problem.

However, at present, quantum computers of a sufficiently large scale to solve real-world combinatorial optimization problems have not yet been realized. However, with the advent of quantum computers, research into the application of combinatorial optimization technology is also underway.

For example, in order to obtain solutions to various combinatorial optimization problems in a general-purpose manner, a simulated annealing method (also referred to as the SA method) that takes as input an energy function in an Ising model or QUBO (Quadratic Unconstrained Binary Optimization) is currently being used. By using the SA method, solutions to combinatorial optimization problems can be obtained even on classical computers.

Patent Literature 1 discloses a simulated annealing device capable of easily obtaining candidate solutions that satisfy multiple constraints imposed on a combinatorial optimization problem. The simulated annealing device described in Patent Literature 1 uses a SAT (Boolean Satisfiability Testing) solver to search for combinations of spins (variables) that satisfy all constraints imposed on the combinatorial optimization problem.

Non-Patent Literature 1 describes a type of constraint known as the weighted sum constraint.

### PRIOR ART DOCUMENTS

### Patent Documents

[Patent Literature 1] International Publication WO2022/264414

### Non-Patent Documents

[Non-Patent Literature 1] Timo Berthold, Stefan Heinz, Marc Pfetsch, “Solving Pseudo-Boolean Problems with SCIP”, ZIB-Report 08-12, March 2008

### SUMMARY OF THE INVENTION

If an energy function in an Ising model or QUBO is applied to a simulated annealing method, solutions to various combinatorial optimization problems can be obtained in a general-purpose manner. However, when an original combinatorial optimization problem is converted into an Ising model or a QUBO format, there is a problem in that the problem space, which is the search range of the solution, increases.

In addition, the simulated annealing device described in Patent Literature 1 requires the use of a SAT solver to obtain a neighboring solution. However, although the use of a SAT solver guarantees that a solution satisfying the constraints can be obtained, there is a problem in that it takes time to obtain the solution.

Accordingly, an exemplary object of the present disclosure is to provide an information processing device, an optimization system, a method, and a program that are capable of simplifying the constraints themselves that are given.

The information processing device according to the present disclosure includes a constraint simplification unit configured to simplify a plurality of constraints that are each expressed as a comparison between a weighted sum of binary variables with integer values and an integer value, by deleting one of the plurality of constraints or deleting a number of binary variables used in any of the plurality of constraints.

The simulated annealing device according to the present disclosure includes: an optimization processing unit configured to execute simulated annealing based on an input constraint expressed as a comparison between a weighted sum of binary variables with integer values and an integer value; and a constraint simplification unit configured to simplify a plurality of constraints by deleting one of the plurality of constraints or deleting a number of binary variables used in any of the plurality of constraints based on the plurality of constraints, wherein the optimization processing unit executes simulated annealing based on the simplified plurality of constraints.

The method according to the present disclosure includes simplifying a plurality of constraints that are each expressed as a comparison between a weighted sum of binary variables with integer values and an integer value, by deleting one of the plurality of constraints or deleting a number of binary variables used in any of the plurality of constraints.

The program according to the present disclosure for causing a computer to execute constraint simplification processing, wherein the constraint simplification processing simplifies a plurality of constraints that are each expressed as a comparison between a weighted sum of binary variables with integer values and an integer value, by deleting one of the plurality of constraints or deleting a number of binary variables used in any of the plurality of constraints.

According to the present disclosure, it is possible to simplify the constraints themselves that are given.

### BRIEF DESCRIPTION OF DRAWINGS

FIG. 1 is an explanatory diagram illustrating a configuration example of the simulated annealing device according to the present disclosure.

FIG. 2 is an explanatory diagram illustrating a configuration example of the constraint simplification unit.

FIG. 3 is a flowchart illustrating an example operation of the determinable variable search unit.

FIG. 4 is a flowchart illustrating an example process of the determinable variable search subroutine.

FIG. 5 is a flowchart illustrating an example operation of the removable constraint search unit.

FIG. 6 is a flowchart illustrating an example process of the removable constraint search subroutine.

FIG. 7 is a block diagram illustrating an overview of the information processing device according to the present disclosure.

FIG. 8 is a block diagram illustrating an overview of the simulated annealing device according to the present disclosure.

FIG. 9 is a schematic block diagram illustrating a configuration of a computer according to at least one example embodiment.

### DETAILED DESCRIPTION OF THE INVENTION

Example embodiments of the present disclosure will now be described with reference to the drawings.

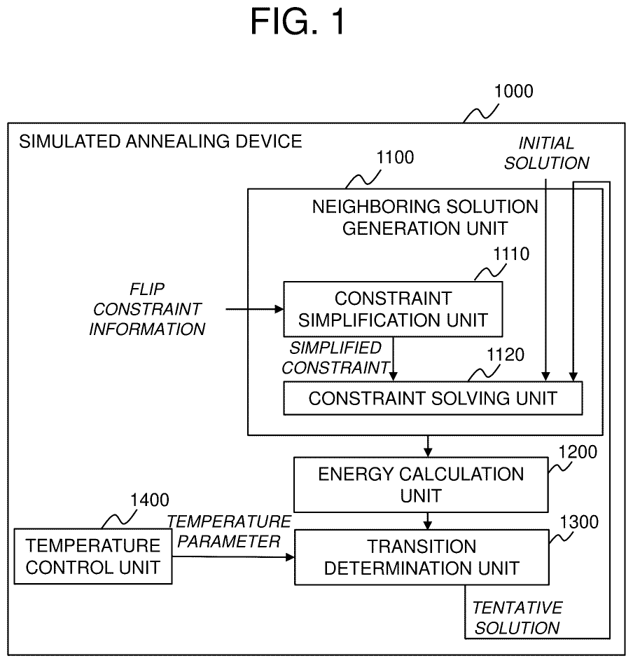

FIG. 1 is an explanatory diagram illustrating a configuration example of the simulated annealing device according to the present disclosure. A simulated annealing device 1000 of the present example embodiment includes a neighboring solution generation unit 1100, an energy calculation unit 1200, a transition determination unit 1300, and a temperature control unit 1400.

As shown in FIG. 1, the neighboring solution generation unit 1100 includes a constraint simplification unit 1110 and a constraint solving unit 1120. The constraint simplification unit 1110 performs processing to simplify given constraints.

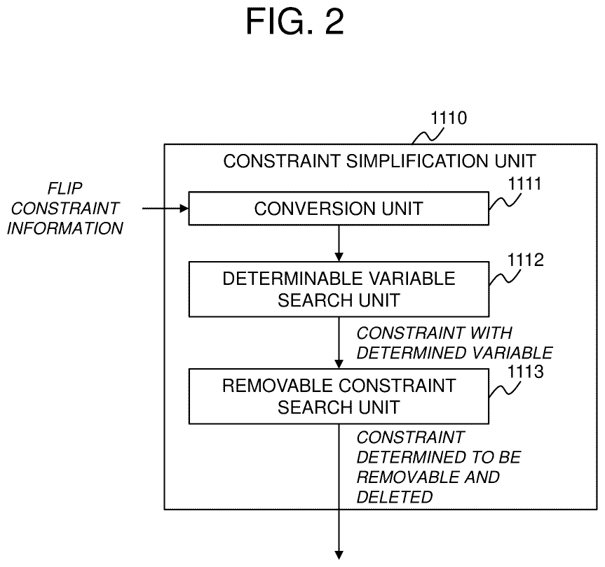

FIG. 2 is an explanatory diagram illustrating a configuration example of the constraint simplification unit 1110 in the present example embodiment. The constraint simplification unit 1110 includes a conversion unit 1111, a determinable variable search unit 1112, and a removable constraint search unit 1113. Note that the one-way arrows shown in FIG. 1 and FIG. 2 simply indicate the direction of information flow and do not exclude bidirectionality.

The conversion unit 1111 receives input of a plurality of constraints to be simplified. In the present disclosure, “simplification” refers to deleting one of the plurality of constraints or deleting a number of binary variables used in any of the plurality of constraints.

In the present example embodiment, information indicating the input constraints may also be referred to as flip constraint information. The flip constraint information indicates constraints imposed on the combinatorial optimization problem to be solved. In the present example embodiment, the conversion unit 1111 receives input of information indicating constraints that can be converted into a one-hot constraint or CNF (Conjunctive Normal Form), as the flip constraint information.

Then, the conversion unit 1111 converts the input constraints into weighted sum constraints. A weighted sum constraint is a constraint expressed as a comparison between a weighted sum of binary variables with integer values and an integer value (more specifically, a constraint indicating that the weighted sum of binary variables with integer values is less than or equal to an integer value). That is, the conversion unit 1111 converts a constraint expressed using binary variables into a weighted sum constraint.

In the following description, binary variables are denoted as vᵢ (1≤i≤n), and the weights that serve as coefficients for the binary variables are denoted as wᵢ (1≤i≤n). Also, an expression representing both vᵢ and ¬vᵢ is referred to as a literal and denoted as lᵢ (1≤i≤n).

CNF can be expressed in the form l₁∨l₂∨ . . . ∨lₙ, which is equivalent to l₁+l₂+ . . . +lₙ≥1, and therefore can be converted into a weighted sum constraint. Also, a one-hot constraint is expressed as v₁+v₂+ . . . +vₙ=1, and thus can also be converted into a weighted sum constraint.

Further, the conversion unit 1111 normalizes the converted weighted sum constraints. Specifically, the conversion unit 1111 normalizes a weighted sum constraint by converting the expression representing the constraint into a form in which all coefficients are positive and the inequality symbol (more specifically, “less than or equal to”, ≤) is used.

For example, suppose that a weighted sum constraint is expressed as w₁l₁+w₂l₂+ . . . +wₙlₙ=1. The conversion unit 1111 converts this expression into two equivalent expressions:

$${w}_{1} {l}_{1} + {w}_{2} {l}_{2} + … + {w}_{n} {l}_{n} \leq 1 , and \qquad ( 1 )$$

$${w}_{1} {l}_{1} + {w}_{2} {l}_{2} + … + {w}_{n} {l}_{n} \geq 1 . \qquad ( 2 )$$

Further, the conversion unit 1111 converts expression (2), which uses the “greater than or equal to” (≥) operator, into an expression using the “less than or equal to” (≤) operator by multiplying both sides of the expression by −1.

Next, if a coefficient wᵢ is negative, then since lᵢ=1−¬lᵢ holds, the conversion unit 1111 substitutes lᵢ=1−¬lᵢ into the negative coefficient to convert the coefficient into a positive value.

After performing the above processing, the conversion unit 1111 may also rearrange the literals in descending order of coefficient size.

The processing of the conversion unit 1111 will be explained below using a concrete example. Suppose that the constraint is given by the expression 3v₁+4v₂+5v₃≥7. First, the conversion unit 1111 multiplies both sides by −1 to convert the expression into −3v₁−4v₂−5v₃≤−7, thereby turning the inequality into “≤”.

Next, the conversion unit 1111 substitutes lᵢ=1−¬lᵢ into each negative coefficient to convert the expression −3v₁−4v₂−5v₃≤−7 into −3(1−¬v₁)−4(1−¬v₂)−5(1−¬v₃)≤−7. By simplifying the transformed expression, the result 3¬v₁+4¬v₂+5¬v₃≤5 is obtained. By rearranging the literals, the normalized result becomes 5¬v₃+4¬v₂+3¬v₁≤5.

The conversion unit 1111 generates normalized weighted sum constraints by converting each of the input plurality of constraints.

The determinable variable search unit 1112 simplifies the plurality of constraints by determining the value of a binary variable included in any of the plurality of constraints. Specifically, the determinable variable search unit 1112 searches for variables whose values can be determined from the relationships among the plurality of constraints and substitutes the determined value into the variable, thereby reducing the number of binary variables. The determinable variable search unit 1112 repeats the process of searching whether the value of a variable can be determined for all the constraints.

For example, suppose there are two constraints: 5x+4y+3z≤7 and y∨z. In this case, if either y or z is 1, then x must be 0. Therefore, these two constraints can be simplified into 4y+3z≤7 and y∨z.

More specifically, y∨z is equivalent to y+z≥1. By transforming (normalizing) this, an expression ¬y+¬z≤1 can be generated. This is derived as follows: multiplying both sides of y+z≥1 by −1 gives −y−z≤−1. Since y=1−¬y and z=1−¬z, substituting these into the constraint yields −1+¬y−1+¬z≤−1, which simplifies to ¬y+¬z≤1.

Since y+¬y=1 and z+¬z=1 hold, multiplying both sides of 5x+4y+3z≤7 and ¬y+¬z≤1 by 3 respectively and then adding both sides of the two expressions results in:

$$5 x + y + 3 ( y + ¬ y ) + 3 ( z + ¬ z ) \leq 7 + 3 ,$$

which simplifies to 5x+y≤4.

Since the coefficient of x is greater than the constant on the right-hand side, it can be determined that x=0.

The generalized processing performed by the determinable variable search unit 1112 for each normalized weighted sum constraint will be described more specifically below. Here, it is assumed that the determinable variable search unit 1112 executes a first subroutine that receives a weighted sum constraint A as input and outputs whether a variable could be determined.

First, let constraint A be expressed as:

$${w}_{{a}^{1}} {l}_{{a}^{1}} + {w}_{{a}^{2}} {l}_{{a}^{2}} + … + {w}_{an} {l}_{an} \leq {C}_{a} ,$$

where the variable of lₐᵢ is denoted as vₐᵢ. The determinable variable search unit 1112 searches, among all constraints other than constraint A, for constraints in which the variables used are a subset of the variables vₐ_{¹}, . . . , vₐₙ used in constraint A, and in which at least one of the subset includes ¬lₐᵢ. Each such constraint found is denoted as constraint B:

$${w}_{{b}_{1}} {l}_{{b}_{1}} + {w}_{{b}_{2}} {l}_{{b}_{2}} + … + {w}_{{b}_{m}} {l}_{{b}_{m}} \leq {C}_{b} .$$

Next, for a selected one of the constraints B, the determinable variable search unit 1112 executes the following processes, Step 1-1 through Step 1-4, for each variable such that ¬lₐᵢ (==l_{b}_{ⱼ}: 1≤j≤m). These processes may also be referred to as loop processing.

(Step 1-1) To eliminate the selected variable, the determinable variable search unit 1112 multiplies both sides of constraints A and B by appropriate coefficients and adds them. Specifically, let LCM be the least common multiple of wₐᵢ and w_{b}_{ᵢ}. Then, the determinable variable search unit 1112 multiplies both sides of constraint A by LCM/wₐᵢ and both sides of constraint B by LCM/w_{b}_{ᵢ}, and then adds the respective sides of constraints A and B.

For example, suppose constraint A is 5x+4y+3z≤7 and constraint B is 3¬y+2¬z≤2, and the goal is to eliminate y. Since the LCM of 4 and 3 is 12, constraint A is multiplied by 3 and constraint B is multiplied by 4 before being added.

(Step 1-2) The determinable variable search unit 1112 rearranges the newly generated constraint obtained by addition, using the identity vᵢ+¬vᵢ=1. Specifically, the determinable variable search unit 1112 eliminates the target variable by substituting vᵢ+¬vᵢ=1 into the variable to be eliminated.

In the above example, the new constraint becomes:

$$15 x + 12 ( y + ¬ y ) + 8 ( z + ¬ z ) \leq 29 .$$

By substituting y+¬y=1 into the expression, the result becomes:

$$15 x + z \leq 9 .$$

(Step 1-3) The determinable variable search unit 1112 searches for a variable whose coefficient is greater than the integer value (constant value) on the right-hand side of the inequality, and determines the value of that variable to be 0.

Since all literal coefficients are positive and the variables are binary variables (either 1 or 0), any variable with a coefficient greater than the right-hand side constant cannot be assigned the value 1 (i.e., it must be 0). For example, in the expression 15x+z≤9 shown above, the coefficient of x is 15, which is greater than the constant value 9 on the right-hand side. Therefore, the expression does not hold when x=1, and x is consequently determined to be 0.

(Step 1-4) When the value of a variable has been determined (to 0), the determinable variable search unit 1112 simplifies the constraints by substituting the determined value into all constraints. Then, the determinable variable search unit 1112 outputs that the variable has been determined and ends the first subroutine. On the other hand, if the value of the variable could not be determined, the determinable variable search unit 1112 recursively executes the first subroutine using the constraint in which the variable was eliminated as the argument (input).

In the recursive execution of the first subroutine, if the value of a variable is successfully determined, the determinable variable search unit 1112 outputs that the variable has been determined and terminates the first subroutine. On the other hand, if the value of the variable cannot be determined, the determinable variable search unit 1112 selects the next variable and continues the above-described loop processing. If none of the variables can be determined, the determinable variable search unit 1112 terminates the loop processing.

Since the number of variables decreases each time the first subroutine is executed, completion of the process is guaranteed in the end.

If the value of a variable could not be determined for the selected constraint, the determinable variable search unit 1112 selects the next constraint and continues the loop processing. If the value of a variable could not be determined for any of the constraints B, the determinable variable search unit 1112 outputs that the value of the variable could not be determined and terminates the first subroutine.

The removable constraint search unit 1113 simplifies the plurality of constraints by deleting one of the constraints that is satisfied. Specifically, the removable constraint search unit 1113 reduces the number of binary variables by deleting the second constraint itself when, based on the relationships among the plurality of constraints, the value or value combination of variables that must be satisfied in the first constraint satisfies the second constraint. The removable constraint search unit 1113 repeats processing to search, for all constraints, whether each constraint is removable or not.

For example, suppose there are two constraints: 5x+4y+3z≤9 and ¬y∨¬z. In this case, if either y or z is 0, then the constraint 5x+4y+3z≤9 will always be satisfied. Therefore, the constraint 5x+4y+3z≤9 can be deleted, and as a result, the constraints can be simplified to just ¬y∨¬z.

More specifically, since ¬y∨¬z is equivalent to ¬y+¬z≥1, this can be transformed (normalized) into the expression y+z≤1. This follows the same reasoning described earlier when determining the values of binary variables.

Now, suppose y is to be eliminated, and the terms other than y are moved to the right-hand side. This yields the expression y≤1−z. Then, the right-hand side (i.e., the terms excluding y) is substituted into the y term of the constraint 5x+4y+3z≤9. As a result of the substitution, since the right-hand side becomes obviously greater, the expression 5x+4y+3z≤5x+4(1−z)+3z=5x−z+4≤9 is obtained.

Next, to normalize the expression such that all coefficients are positive, z=1−¬z is substituted into the result, yielding 5x−(1−¬z)+4=5x+¬z+3≤9. By simplifying, the result becomes 5x+¬z≤6.

In the expression 5x+¬z≤6, the sum of the coefficients on the left-hand side is 6. Since both x and z are binary variables, the value of the left-hand side is always less than or equal to 6. Therefore, it can be seen that the expression always holds. If 5x+¬z+3≤9 always holds, and 5x+4y+3z≤5x+¬z+3, then it follows that the original constraint 5x+4y+3z≤9 always holds as well.

The generalized processing performed by the removable constraint search unit 1113 for each normalized weighted sum constraint will now be described in detail. Here, it is assumed that the removable constraint search unit 1113 executes a second subroutine, which receives a weighted sum constraint A as input and outputs whether the constraint was removable.

First, let constraint A be expressed as wₐ_{¹}lₐ_{¹}+wₐ_{²}lₐ_{²}+ . . . +wₐₙlₐₙ≤Cₐ, and let the variable of lₐᵢ be denoted as vₐᵢ. The removable constraint search unit 1113 searches, among all constraints other than constraint A, for constraints in which the variables used are a subset of the variables vₐ_{¹}, . . . , vₐₙ used in constraint A, and in which at least one of the subset includes lₐᵢ. Each such constraint found is denoted as constraint B:

$${w}_{{b}_{1}} {l}_{{b}_{1}} + {w}_{{b}_{2}} {l}_{{b}_{2}} + … + {w}_{{b}_{m}} {l}_{{b}_{m}} \leq {C}_{b} .$$

Next, for a selected one of the constraints B, the removable constraint search unit 1113 executes the following processes, Step 2-1 through Step 2-4, for each variable such that lₐᵢ (==l_{b}_{ⱼ}: 1≤j≤m). These processes may also be referred to as loop processing.

(Step 2-1) The removable constraint search unit 1113 transforms the selected constraint so that the literal to be eliminated appears on the left-hand side, in the form: w_{b}_{ⱼ}l_{b}_{ⱼ}≤C_{b}−w_{b}_{₁}l_{b}_{₁}−w_{b}_{₂}l_{b}_{₂}− . . . −w_{b}_{ₘ}l_{b}_{ₘ} (provided that the right-hand side does not include the term w_{b}_{ⱼ}l_{b}_{ⱼ}).

The removable constraint search unit 1113 may, for example, first select w_{b}_{₁}l_{b}_{₁} as w_{b}_{ⱼ}l_{b}_{ⱼ}).

(Step 2-2) To eliminate the selected literal l_{b}_{ⱼ} (whose variable is vₐⱼ), the removable constraint search unit 1113 multiplies both sides of each of constraints A and B by appropriate coefficients and substitutes the variable. Specifically, let LCM be the least common multiple of wₐᵢ and w_{b}_{ᵢ}. The removable constraint search unit 1113 multiplies both sides of constraint A by LCM/wₐᵢ, and both sides of constraint B by LCM/w_{b}_{ᵢ}. Then, the removable constraint search unit 1113 replaces the term LCM/wₐᵢl_{b}_{ᵢ} with the expression:

$$( LCM / {w}_{{b}_{j}} ) \cdot {C}_{b} - ( LCM / {w}_{{b}_{j}} ) \cdot {w}_{{b}_{1}} {l}_{{b}_{1}} - … - ( LCM / {w}_{{b}_{j}} ) \cdot {w}_{{b}_{m}} {l}_{{b}_{m}} .$$

Furthermore, the removable constraint search unit 1113 rearranges the resulting expression using the identity vᵢ+¬vᵢ=1.

For example, suppose constraint A is 5x+4y+3z≤7 and constraint B is 3y+2z≤2, with the goal of eliminating y. From the expression 3y≤2−2z, and since the LCM of 4 and 3 is 12, multiplying constraint A by 3 and constraint B by 4 results in the following:

$$15 x + 12 y + 9 z \leq 21 \qquad constraint A$$

$$12 y \leq 8 - 8 z . \qquad constraint B$$

Substituting the 12y term in constraint A with the right-hand side of constraint B gives 15x+(8 −8z)+9z≤21, which simplifies to 15x+z≤13.

(Step 2-3) The removable constraint search unit 1113 determines whether the sum of the coefficients on the left-hand side of the resulting expression is less than or equal to the constant on the right-hand side. If the sum of the coefficients on the left-hand side is less than or equal to the right-hand side constant, the removable constraint search unit 1113 determines that the constraint is removable, deletes constraint A, outputs that the constraint was removable, and ends the second subroutine.

Since all literal coefficients are positive and the variables are binary variables (either 1 or 0), the left-hand side reaches its maximum value when all variables are set to 1. For example, in the expression 15x+z≤13, the sum of the coefficients on the left-hand side is 16, which is greater than the constant 13 on the right-hand side. Therefore, the constraint is determined to be non-removable.

(Step 2-4) If the constraint is determined to be non-removable, the removable constraint search unit 1113 recursively executes the second subroutine using the constraint in which the variable has been eliminated as the input.

In the recursive second subroutine, if the constraint is determined to be removable, the removable constraint search unit 1113 deletes the constraint, outputs that the constraint was removable, and ends the second subroutine. On the other hand, if the constraint is not determined to be removable, the removable constraint search unit 1113 selects the next variable and continues the above-described loop processing. If no constraints could be deleted after processing all variables, the removable constraint search unit 1113 terminates the loop processing.

If the selected constraint is not removable, the removable constraint search unit 1113 selects the next constraint and continues the above-described loop processing. If no constraints could be deleted after processing all of the constraints B, the removable constraint search unit 1113 outputs that the constraint could not be deleted and ends the second subroutine.

In the present example embodiment, the case has been illustrated where the constraint simplification unit 1110 includes the conversion unit 1111, the determinable variable search unit 1112, and the removable constraint search unit 1113. Note, however, that when normalized weighted sum constraints are input in advance, the constraint simplification unit 1110 may not include the conversion unit 1111.

The constraint simplification unit 1110 may include either the determinable variable search unit 1112, the removable constraint search unit 1113, or both. Preferably, the constraint simplification unit 1110 includes both the determinable variable search unit 1112 and the removable constraint search unit 1113, since doing so increases the likelihood of further simplifying the constraints. Note that the order in which the processing by the determinable variable search unit 1112 and the processing by the removable constraint search unit 1113 are performed is arbitrary.

The constraint simplification unit 1110 may generate an energy function for a combinatorial optimization problem expressed in an Ising model (QUBO model), based on the simplified constraints. For example, a QUBO model for a traveling salesman problem may be expressed by the following expression (Expression 1). Note that since methods for generating energy functions are widely known, detailed explanation is omitted here.

$$H = α {\sum }_{v = 1}^{n} {( 1 - {\sum }_{j = 1}^{N} {x}_{v , j} )}^{2} + α {\sum }_{j = 1}^{n} {( 1 - {\sum }_{v = 1}^{N} {x}_{v , j} )}^{2} + β {\sum }_{( uv ) ∈ E} {W}_{uv} {\sum }_{j = 1}^{N} {x}_{u , j} {x}_{v , j + 1} \qquad ( Expression 1 )$$

The constraint solving unit 1120 obtains a candidate solution to the combinatorial optimization problem based on the input constraints. The constraint solving unit 1120 may obtain a candidate solution, for example, by using a SAT solver. However, the method used by the constraint solving unit 1120 to obtain a candidate solution is not limited to the use of a SAT solver, and any known method may be used.

The energy calculation unit 1200 calculates an energy difference Δ based on an input candidate solution. Assuming that the above-described SA method is used, the energy calculation unit 1200 selects one spin from the state representing the candidate solution and calculates the energy difference Δ that results from flipping the selected spin. As for the calculation of energy, for example, the above-described energy function may be used.

The transition determination unit 1300 determines whether to accept the flip of a spin in the candidate solution, based on the energy difference Δ. If the flip is accepted, the transition determination unit 1300 flips the spin in the candidate solution. For example, if the energy difference Δ is negative, the transition determination unit 1300 may accept the spin flip. If the energy difference Δ is positive, the transition determination unit 1300 may accept the spin flip with a transition probability of min(exp(−Δ/T), 1). Here, T is a temperature parameter, which will be described later.

The temperature control unit 1400 controls the temperature parameter T used in the SA method. Specifically, the temperature control unit 1400 decreases the temperature parameter T as the solution process progresses over time.

As described above, the constraint solving unit 1120, the energy calculation unit 1200, the transition determination unit 1300, and the temperature control unit 1400 included in the neighboring solution generation unit 1100 execute processing to obtain an optimal solution based on the constraints simplified by the constraint simplification unit 1110. Therefore, these units collectively may be referred to as the optimization processing unit.

In addition, the neighboring solution generation unit 1100 (more specifically, the constraint simplification unit 1110) in the present example embodiment can be said to improve the capability of the computer performing the optimization processing by simplifying the constraints used in the combinatorial optimization problem.

The constraint simplification unit 1110 (more specifically, the conversion unit 1111, the determinable variable search unit 1112, and the removable constraint search unit 1113) is implemented by a processor (e.g., CPU (Central Processing Unit), GPU (Graphics Processing Unit)) of a computer operating in accordance with a program.

For example, the program may be stored in a storage unit (not shown) of the simulated annealing device 1000. The processor may read the program and, in accordance with the program, operate as the constraint simplification unit 1110 (more specifically, the conversion unit 1111, the determinable variable search unit 1112, and the removable constraint search unit 1113). Alternatively, the functions of the constraint simplification unit 1110 may be provided in a SaaS (Software as a Service) format.

Furthermore, each component of the constraint simplification unit 1110 (more specifically, the conversion unit 1111, the determinable variable search unit 1112, and the removable constraint search unit 1113) may be implemented by dedicated hardware. Additionally, some or all of the components of each unit may be implemented by general-purpose or dedicated circuitry, processors, or combinations thereof. These may be configured on a single chip or configured using multiple chips connected via a bus. Some or all of the components of each unit may also be implemented by a combination of the above-mentioned circuitry and a program.

Moreover, when some or all of the components of the constraint simplification unit 1110 (more specifically, the conversion unit 1111, the determinable variable search unit 1112, and the removable constraint search unit 1113) are implemented by a plurality of information processing devices or circuits, those devices or circuits may be centrally located or distributed. For example, the information processing devices or circuits may be implemented in a form in which they are connected to each other via a communication network, such as in a client-server system or a cloud computing system.

In addition to the neighboring solution generation unit 1100, the energy calculation unit 1200, the transition determination unit 1300, and the temperature control unit 1400 may also be implemented by a processor of a computer operating in accordance with a program.

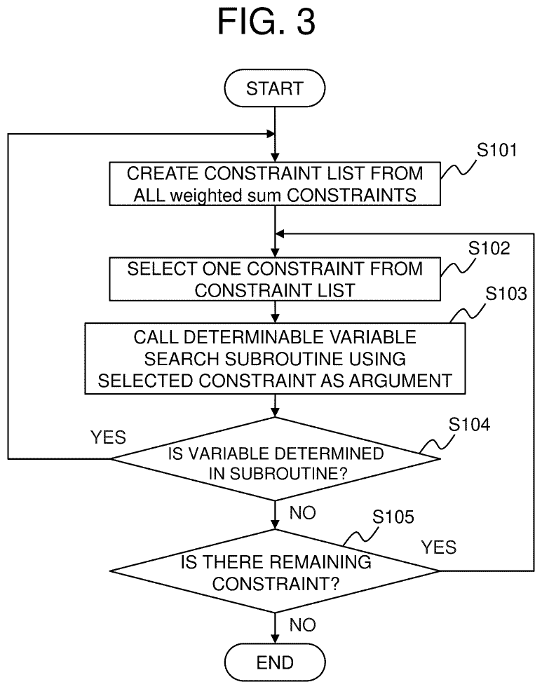

Next, the operation of the simulated annealing device in the present example embodiment will be described. First, the operation of the determinable variable search unit 1112 in the present embodiment will be explained. The determinable variable search unit 1112 simplifies a plurality of constraints by determining the value of a binary variable included in any of the constraints. FIG. 3 is a flowchart illustrating an example operation of the determinable variable search unit 1112. In the operation example shown in FIG. 3, it is assumed that a plurality of normalized weighted sum constraints are input.

The determinable variable search unit 1112 creates a constraint list from all the weighted sum constraints (Step S101). The determinable variable search unit 1112 selects one constraint from the created constraint list (Step S102), and calls the determinable variable search subroutine (corresponding to the aforementioned first subroutine) using the selected constraint as an argument (Step S103).

The determinable variable search unit 1112 refers to the output of the subroutine and determines whether a variable could be determined (Step S104). If a variable was determined (YES in Step S104), the processing from Step S101 onward is repeated. On the other hand, if a variable could not be determined (NO in Step S104), the determinable variable search unit 1112 determines whether there are still remaining target constraints (Step S105).

If there are remaining constraints (YES in Step S105), the processing from Step S102 onward is repeated. If there are no more target constraints (NO in Step S105), the process is terminated.

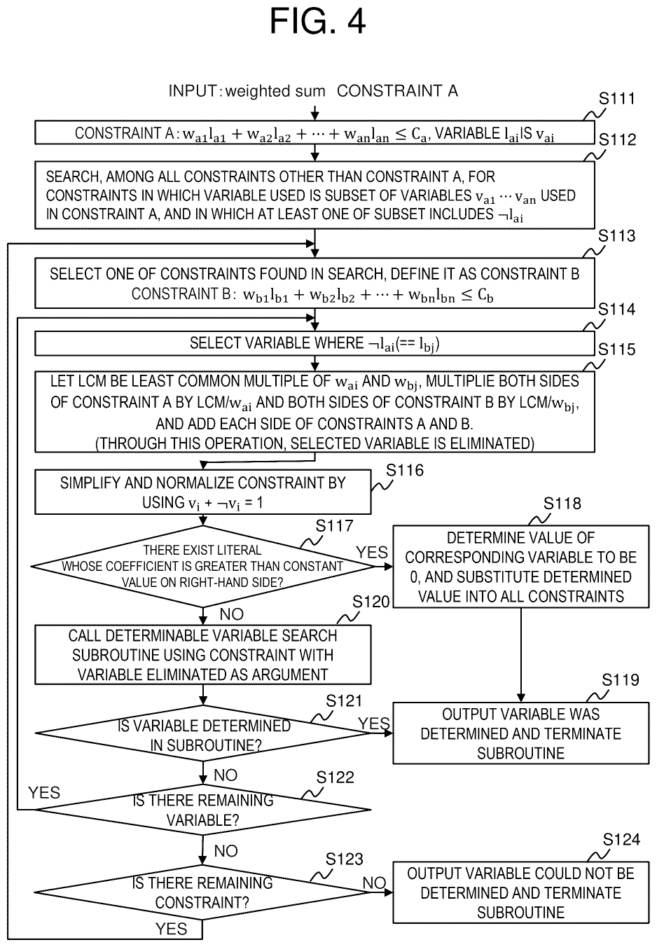

FIG. 4 is a flowchart illustrating an example process of the determinable variable search subroutine. The input in this processing example is the weighted sum constraint A.

First, constraint A is expressed as wₐ_{¹}lₐ_{¹}+wₐ_{²}lₐ_{²}+ . . . +wₐₙlₐₙ≤Cₐ, and the variable of lₐᵢ is denoted as vₐᵢ (Step S111). The determinable variable search unit 1112 searches, among all constraints other than constraint A, for constraints in which the variables used are a subset of the variables vₐ_{¹}, . . . , vₐₙ used in constraint A, and in which at least one of the subset includes ¬lₐᵢ (Step S112).

The determinable variable search unit 1112 selects one of the constraints found in the search and defines it as constraint B:

$${w}_{{b}_{1}} {l}_{{b}_{1}} + {w}_{{b}_{2}} {l}_{{b}_{2}} + … + {w}_{{b}_{m}} {l}_{{b}_{m}} \leq {C}_{b} . \qquad ( Step S113 )$$

The determinable variable search unit 1112 selects a variable for which ¬lₐᵢ (==l_{b}_{ⱼ}) holds (Step S114).

Let LCM be the least common multiple of wₐᵢ and w_{b}_{ᵢ}. The determinable variable search unit 1112 multiplies both sides of constraint A by LCM/wₐᵢ and both sides of constraint B by LCM/w_{b}_{ᵢ}, and then adds each side of constraints A and B. Through this operation, the selected variable is eliminated (Step S115).

The determinable variable search unit 1112 simplifies and normalizes the newly generated constraint by using the identity vᵢ+¬vᵢ=1 (Step S116). The determinable variable search unit 1112 determines whether there exists a literal whose coefficient is greater than the constant value on the right-hand side (Step S117). If such a literal exists (YES in Step S117), the determinable variable search unit 1112 determines the value of the corresponding variable to be 0 and substitutes the determined value into all constraints (Step S118). Then, the determinable variable search unit 1112 outputs that the variable has been determined and terminates the subroutine (Step S119).

On the other hand, if no such literal exists (NO in Step S117), the determinable variable search unit 1112 recursively calls the determinable variable search subroutine using the constraint with the variable eliminated as an argument (Step S120). Then, the determinable variable search unit 1112 determines whether the variable was successfully determined in the recursively called subroutine (Step S121). If the variable was determined (YES in Step S121), the determinable variable search unit 1112 outputs that the variable was determined and terminates the subroutine (Step S119).

On the other hand, if the variable could not be determined (NO in Step S121), the determinable variable search unit 1112 determines whether there are still remaining target variables (Step S122). If there are remaining variables (YES in Step S122), the processing from Step S114 onward is repeated. If there are no remaining target variables (NO in Step S122), the determinable variable search unit 1112 determines whether there are still remaining target constraints (Step S123).

If there are remaining target constraints (YES in Step S123), the processing from Step S113 onward is repeated. If there are no remaining target constraints (NO in Step S123), the determinable variable search unit 1112 outputs that the variable could not be determined and terminates the subroutine (Step S124).

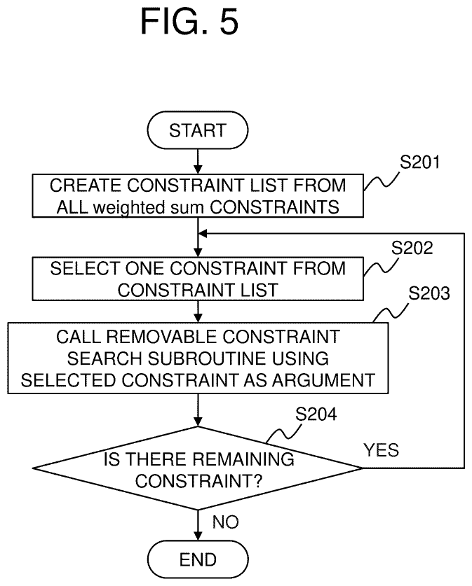

Next, the operation of the removable constraint search unit 1113 in the present example embodiment will be described. The removable constraint search unit 1113 simplifies a plurality of constraints by deleting one of the plurality of constraints that is satisfied. FIG. 5 is a flowchart illustrating an example operation of the removable constraint search unit 1113. In the operation example shown in FIG. 5, it is also assumed that a plurality of normalized weighted sum constraints are input.

The removable constraint search unit 1113 creates a constraint list from all the weighted sum constraints (Step S201). The removable constraint search unit 1113 selects one constraint from the created constraint list (Step S202), and calls the removable constraint search subroutine (corresponding to the aforementioned second subroutine) using the selected constraint as an argument (Step S203).

The removable constraint search unit 1113 refers to the output of the subroutine and determines whether there are still remaining target constraints (Step S204). If there are remaining constraints (YES in Step S204), the processing from Step S202 onward is repeated. If there are no more target constraints (NO in Step S204), the process is terminated.

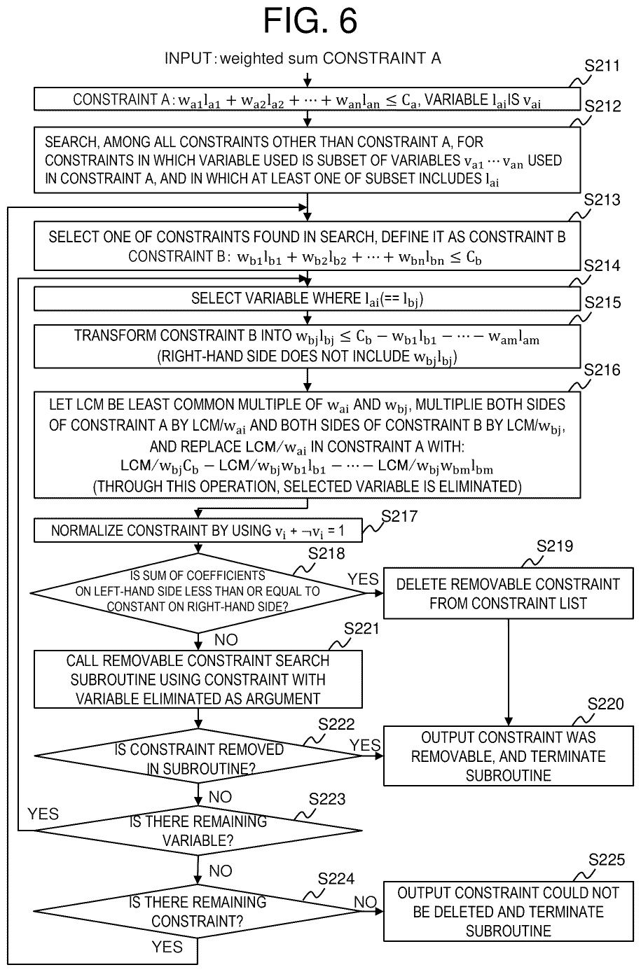

FIG. 6 is a flowchart illustrating an example process of the removable constraint search subroutine. In this process example, the input is also the weighted sum constraint A.

First, constraint A is expressed as wₐ_{¹}lₐ_{¹}+wₐ_{²}lₐ_{²}+ . . . +wₐₙlₐₙ≤Cₐ, and the variable of lₐᵢ is denoted as vₐᵢ (Step S211). The removable constraint search unit 1113 searches, among all constraints other than constraint A, for constraints in which the variables used are a subset of the variables vₐ_{¹}, . . . , vₐₙ used in constraint A, and in which at least one of the subset includes lₐᵢ (Step S212).

The removable constraint search unit 1113 selects one of the constraints found in the search and defines it as constraint B:

$${w}_{{b}_{1}} {l}_{{b}_{1}} + {w}_{{b}_{2}} {l}_{{b}_{2}} + … + {w}_{{b}_{m}} {l}_{{b}_{m}} \leq {C}_{b} . \qquad ( Step S213 )$$

The removable constraint search unit 1113 selects a variable for which lₐᵢ=l_{b}_{ⱼ} holds (Step S214). Then, the removable constraint search unit 1113 transforms constraint B into the form:

$${w}_{{b}_{j}} {l}_{{b}_{j}} \leq {C}_{b} - {w}_{{b}_{1}} {l}_{{b}_{1}} - … - {w}_{{b}_{m}} {l}_{{b}_{m}} ,$$

where the right-hand side does not include the term w_{b}_{ⱼ}l_{b}_{ⱼ} (Step S215).

Let LCM be the least common multiple of wₐᵢ and w_{b}_{ᵢ}. The removable constraint search unit 1113 multiplies both sides of constraint A by LCM/wₐᵢ and both sides of constraint B by LCM/w_{b}_{ᵢ}. Then, the removable constraint search unit 1113 replaces the LCM/wₐᵢl_{b}_{ᵢ} term in constraint A with:

$$( LCM / {w}_{{b}_{j}} ) \cdot {C}_{b} - ( LCM / {w}_{{b}_{j}} ) \cdot {w}_{{b}_{1}} {l}_{{b}_{1}} - … - ( LCM / {w}_{{b}_{j}} ) \cdot {w}_{{b}_{m}} {l}_{{b}_{m}} .$$

Through this operation, the target variable is eliminated (Step S216). The removable constraint search unit 1113 further normalizes the resulting expression using the identity vᵢ+¬vᵢ=1 (Step S217).

The removable constraint search unit 1113 determines whether the total sum of the coefficients on the left-hand side is less than or equal to the constant on the right-hand side (Step S218). If the sum is less than or equal (YES in Step S218), the removable constraint search unit 1113 determines that the constraint is removable, deletes the removable constraint from the constraint list (Step S219), outputs that the constraint was removable, and terminates the subroutine (Step S220).

On the other hand, if the sum is not less than or equal to the constant (NO in Step S218), the removable constraint search unit 1113 recursively calls the removable constraint search subroutine using the constraint in which the variable was eliminated as the input (Step S221). Then, the removable constraint search unit 1113 determines whether the constraint was successfully removed in the recursive call (Step S222). If the constraint was removed (YES in Step S222), the removable constraint search unit 1113 outputs that the constraint was removable and terminates the subroutine (Step S220).

On the other hand, if the constraint was not removed (NO in Step S222), the removable constraint search unit 1113 determines whether there are still remaining target variables (Step S223). If there are remaining variables (YES in Step S223), the processing from Step S214 onward is repeated. If there are no remaining target variables (NO in Step S223), the removable constraint search unit 1113 determines whether there are still remaining target constraints (Step S224).

If there are remaining target constraints (YES in Step S224), the processing from Step S213 onward is repeated. If there are no remaining target constraints (NO in Step S224), the removable constraint search unit 1113 outputs that the constraint could not be deleted and terminates the subroutine (Step S225).

As described above, in the present example embodiment, the constraint simplification unit 1110 simplifies a plurality of constraints, which are each expressed as a comparison between a weighted sum of binary variables with integer values and an integer value, by deleting one of the constraints or by deleting a number of binary variables used in any of the constraints. In this way, the constraints themselves that are given can be simplified.

Next, a specific example in which the simulated annealing device of the present disclosure is applied will be described. In this example, a case will be described where the simulated annealing device of the present disclosure is applied to a portfolio optimization problem.

In the portfolio optimization problem, for each of a plurality of stocks, an expected return and a risk (variance) are given. The problem involves finding a combination of stocks that minimizes risk while achieving at least a certain level of expected return. In this example, the variables are expressed in binary form to indicate whether a stock is selected for purchase or not, and the number of stocks to be purchased is assumed to be fixed.

Let the stocks be denoted as v₁ through vₙ, and the expected returns for each stock be denoted as w₁ through wₙ. Then, the constraints for the portfolio optimization problem are expressed as follows:

$${w}_{1} {v}_{1} + {w}_{2} {v}_{2} + … + {w}_{n} {v}_{n} \geq expected return$$

$${v}_{1} + {v}_{2} + … + {v}_{n} = number of stocks$$

Under these constraints, it is assumed that the sum of the risks for each stock, expressed in a QUBO matrix, is minimized. The expected return for each stock, the total required expected return, and the number of stocks can each take arbitrary values as input during optimization. Depending on the values, the proposed method may allow the constraints to be simplified.

For example, suppose the constraints regarding expected return and number of stocks are given as follows:

$$10 {v}_{1} + 9 {v}_{2} + 8 {v}_{3} + 4 {v}_{4} \geq 15$$

$${v}_{1} + {v}_{2} + {v}_{3} + {v}_{4} = 2$$

The constraint simplification unit 1110 derives the following expressions by normalizing these equations:

$$10 ¬ {v}_{1} + 9 ¬ {v}_{2} + 8 ¬ {v}_{3} + 4 ¬ {v}_{4} \leq 16 \qquad ( Expression C1 )$$

$${v}_{1} + {v}_{2} + {v}_{3} + {v}_{4} \leq 2 \qquad ( Expression C2 )$$

$$¬ {v}_{1} + ¬ {v}_{2} + ¬ {v}_{3} + ¬ {v}_{4} \leq 2 \qquad ( Expression C3 )$$

As described in the processing of the determinable variable search unit 1112 above, Expression C1 is simplified using Expression C2 by eliminating variable v₁, yielding:

$${v}_{2} + 2 {v}_{3} + 6 {v}_{4} \leq 5$$

Since the coefficient of v₄ (which is 6) is greater than the right-hand side value 5, it can be determined that v₄=0.

Also, for example, suppose the constraints regarding expected return and number of stocks are given as follows:

$$10 {v}_{1} + 9 {v}_{2} + 8 {v}_{3} + 7 {v}_{4} \geq 14$$

$${v}_{1} + {v}_{2} + {v}_{3} + {v}_{4} = 2$$

The constraint simplification unit 1110 derives the following expressions by normalizing these equations:

$$10 ¬ {v}_{1} + 9 ¬ {v}_{2} + 8 ¬ {v}_{3} + 7 ¬ {v}_{4} \leq 20 \qquad ( Expression D1 )$$

$${v}_{1} + {v}_{2} + {v}_{3} + {v}_{4} \leq 2 \qquad ( Expression D2 )$$

$$¬ {v}_{1} + ¬ {v}_{2} + ¬ {v}_{3} + ¬ {v}_{4} \leq 2 \qquad ( Expression D3 )$$

As shown in the processing of the removable constraint search unit 1113 above, Expression D1 is targeted, and variable v₁ is eliminated using Expression D3 as follows:

$$10 ¬ {v}_{1} + 9 ¬ {v}_{2} + 8 ¬ {v}_{3} + 7 ( 2 - ¬ {v}_{1} - ¬ {v}_{2} - ¬ {v}_{3} ) \leq 20$$

This simplifies to:

$$3 ¬ {v}_{1} + 2 ¬ {v}_{2} + ¬ {v}_{3} \leq 20 - 14 = 6$$

Since the sum of the coefficients on the left-hand side, 3+2+1=6, is less than or equal to 6, it can be concluded that the constraint 10v₁+9v₂+8v₃+7v₄≥14 can be deleted.

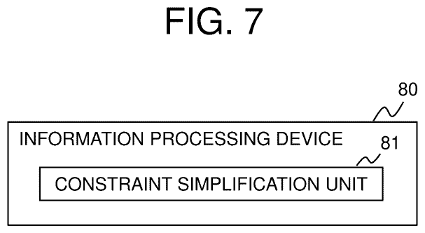

Next, an overview of the present disclosure will be described. FIG. 7 is a block diagram illustrating an overview of the information processing device according to the present disclosure. An information processing device 80 according to the present disclosure comprises a constraint simplification unit 81 (e.g., the constraint simplification unit 1110) that simplifies a plurality of constraints that are each expressed as a comparison between a weighted sum of binary variables with integer values and an integer value, by deleting one of the constraints or deleting a number of binary variables used in any of the plurality of constraints.

With such a configuration, the constraints themselves that are given can be simplified.

The constraint simplification unit 81 (e.g., the determinable variable search unit 1112) may simplify the plurality of constraints by determining a value of a binary variable included in any of the plurality of constraints.

Specifically, the constraint simplification unit 81 may determine the value of the binary variable to be 0 when the coefficient of the binary variable, which is an integer value, is greater than the integer value used in the comparison.

Additionally, the constraint simplification unit 81 (e.g., the removable constraint search unit 1113) may simplify the plurality of constraints by deleting one of the plurality of constraints that is satisfied.

Specifically, the constraint simplification unit 81 may delete one of the constraints that generated an expression in which the sum of the integer coefficients of the binary variables is less than or equal to the integer value used in the comparison.

Moreover, the constraint simplification unit 81 may simplify the plurality of constraints based on a plurality of constraints that indicate that a weighted sum of binary variables with positive integer values is less than or equal to a predetermined integer value (e.g., normalized weighted sum constraints).

Further, the constraint simplification unit 81 may convert a constraint expressed using binary variables into a weighted sum constraint, normalize the converted weighted sum constraint, and simplify the plurality of constraints based on the normalized weighted sum constraints.

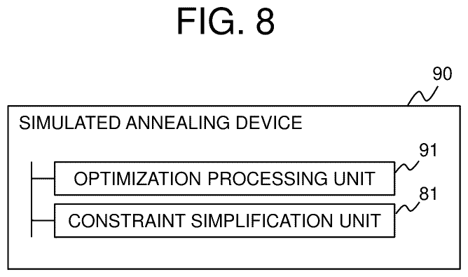

FIG. 8 is a block diagram illustrating an overview of the simulated annealing device according to the present disclosure. A simulated annealing device 90 according to the present disclosure includes: an optimization processing unit 91 (e.g., the constraint solving unit 1120, the energy calculation unit 1200, the transition determination unit 1300, and the temperature control unit 1400) configured to execute simulated annealing based on an input constraint expressed as a comparison between a weighted sum of binary variables with integer values and an integer value; and a constraint simplification unit 81. The details of the constraint simplification unit 81 are the same as those illustrated in FIG. 7.

The optimization processing unit 91 executes simulated annealing based on the simplified plurality of constraints.

With such a configuration, by simplifying the constraints used in the combinatorial optimization problem, the capability of the computer that performs the optimization processing can be improved.

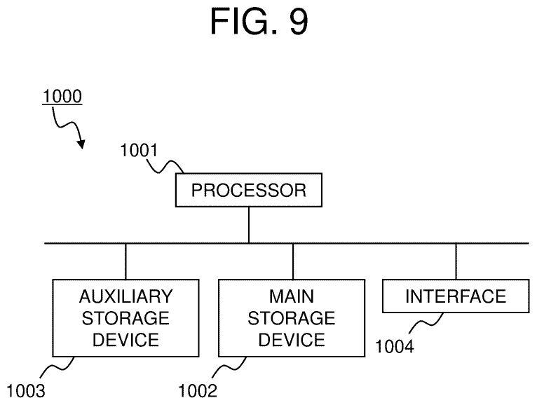

FIG. 9 is a schematic block diagram illustrating a configuration of a computer according to at least one example embodiment. A computer 1000 includes a processor 1001, a main storage device 1002, an auxiliary storage device 1003, and an interface 1004.

The above-described information processing device 80 and simulated annealing device 90 are implemented on the computer 1000. The operations of the above-mentioned processing units are stored in the auxiliary storage device 1003 in the form of a program. The processor 1001 reads the program from the auxiliary storage device 1003, loads it into the main storage device 1002, and executes the above-described processing in accordance with the program.

In at least one example embodiment, the auxiliary storage device 1003 is one example of a non-transitory tangible medium. Other examples of non-transitory tangible media include a magnetic disk, a magneto-optical disk, a CD-ROM (Compact Disc Read-only Memory), a DVD-ROM (Read-only Memory), or a semiconductor memory, all of which may be connected via the interface 1004. When the program is delivered to the computer 1000 via a communication line, the computer 1000 receiving the delivery may deploy that program in the main storage device 1002 and execute the above processing.

Moreover, the program may be intended to implement only part of the functions described above. Furthermore, the program may be a so-called difference file (difference program) that implements the functions described above in combination with another program already stored in the auxiliary storage device 1003.

Some or all of the example embodiments described above may also be described as follows, but are not limited thereto.

(Supplementary Note 1) An information processing device comprising a constraint simplification unit configured to simplify a plurality of constraints that are each expressed as a comparison between a weighted sum of binary variables with integer values and an integer value, by deleting one of the plurality of constraints or deleting a number of binary variables used in any of the plurality of constraints.

(Supplementary Note 2) The information processing device according to Supplementary Note 1, wherein the constraint simplification unit simplifies the plurality of constraints by determining a value of a binary variable included in any of the plurality of constraints.

(Supplementary Note 3) The information processing device according to Supplementary Note 2, wherein the constraint simplification unit determines the value of the binary variable to be 0 when the coefficient of the binary variable, which is an integer value, is greater than the integer value used in the comparison.

(Supplementary Note 4) The information processing device according to Supplementary Note 1 or 2, wherein the constraint simplification unit simplifies the plurality of constraints by deleting one of the plurality of constraints that is satisfied.

(Supplementary Note 5) The information processing device according to Supplementary Note 4, wherein the constraint simplification unit deletes one of the constraints that generated an expression in which the sum of the integer coefficients of the binary variables is less than or equal to the integer value used in the comparison.

(Supplementary Note 6) The information processing device according to Supplementary Note 1, wherein the constraint simplification unit simplifies the plurality of constraints based on a plurality of constraints that indicate that a weighted sum of binary variables with positive integer values is less than or equal to a predetermined integer value.

(Supplementary Note 7) The information processing device according to Supplementary Note 1, wherein the constraint simplification unit converts a constraint expressed using binary variables into a weighted sum constraint, normalizes the converted weighted sum constraint, and simplifies the plurality of constraints based on the normalized weighted sum constraint.

(Supplementary Note 8) A simulated annealing device comprising:
an optimization processing unit configured to execute simulated annealing based on an input constraint expressed as a comparison between a weighted sum of binary variables with integer values and an integer value; and
a constraint simplification unit configured to simplify a plurality of constraints by deleting one of the plurality of constraints or deleting a number of binary variables used in any of the plurality of constraints based on the plurality of constraints,
wherein the optimization processing unit executes simulated annealing based on the simplified plurality of constraints.

(Supplementary Note 9) A method comprising simplifying a plurality of constraints that are each expressed as a comparison between a weighted sum of binary variables with integer values and an integer value, by deleting one of the plurality of constraints or deleting a number of binary variables used in any of the plurality of constraints.

(Supplementary Note 10) A simulated annealing method comprising:
executing simulated annealing based on an input constraint expressed as a comparison between a weighted sum of binary variables with integer values and an integer value;
simplifying a plurality of constraints by deleting one of the constraints or deleting a number of binary variables used in any of the constraints based on the plurality of constraints, and
executing simulated annealing based on the simplified plurality of constraints.

(Supplementary Note 11) A program for causing a computer to execute constraint simplification processing, wherein the constraint simplification processing simplifies a plurality of constraints that are each expressed as a comparison between a weighted sum of binary variables with integer values and an integer value, by deleting one of the plurality of constraints or deleting a number of binary variables used in any of the plurality of constraints.

(Supplementary Note 12) A program for causing a computer to execute:
an optimization process that executes simulated annealing based on an input constraint expressed as a comparison between a weighted sum of binary variables with integer values and an integer value; and
a constraint simplification process that simplifies a plurality of constraints by deleting one of the plurality of constraints or deleting a number of binary variables used in any of the plurality of constraints based on the plurality of constraints,
wherein, in the optimization process, simulated annealing is executed based on the simplified plurality of constraints.

While the present disclosure has been explained with reference to the example embodiments and examples, the present disclosure is not limited to these example embodiments and examples. Various modifications can be made to the configuration and details of the present invention within the scope of the present disclosure as understood by those skilled in the art.

1. An information processing device comprising:
a memory storing instructions; and
one or more processors configured to execute the instructions to simplify a plurality of constraints that are each expressed as a comparison between a weighted sum of binary variables with integer values and an integer value, by deleting one of the plurality of constraints or deleting a number of binary variables used in any of the plurality of constraints.

2. The information processing device according to claim 1,
wherein the processor is configured to execute the instructions to simplify the plurality of constraints by determining a value of a binary variable included in any of the plurality of constraints.

3. The information processing device according to claim 2,
wherein the processor is configured to execute the instructions to determine the value of the binary variable to be 0 when the coefficient of the binary variable, which is an integer value, is greater than the integer value used in the comparison.

4. The information processing device according to claim 1,
wherein the processor is configured to execute the instructions to simplify the plurality of constraints by deleting one of the plurality of constraints that is satisfied.

5. The information processing device according to claim 4,
wherein the processor is configured to execute the instructions to delete one of the constraints that generated an expression in which the sum of the integer coefficients of the binary variables is less than or equal to the integer value used in the comparison.

6. The information processing device according to claim 1,
wherein the processor is configured to execute the instructions to simplify the plurality of constraints based on a plurality of constraints that indicate that a weighted sum of binary variables with positive integer values is less than or equal to a predetermined integer value.

7. The information processing device according to claim 1,
wherein the processor is configured to execute the instructions to convert a constraint expressed using binary variables into a weighted sum constraint, normalize the converted weighted sum constraint, and simplify the plurality of constraints based on the normalized weighted sum constraint.

8. A simulated annealing device comprising:
a memory storing instructions; and
one or more processors configured to execute the instructions to:
execute simulated annealing based on an input constraint expressed as a comparison between a weighted sum of binary variables with integer values and an integer value;
simplify a plurality of constraints by deleting one of the plurality of constraints or deleting a number of binary variables used in any of the plurality of constraints based on the plurality of constraints; and
execute simulated annealing based on the simplified plurality of constraints.

9. A method comprising
simplifying a plurality of constraints that are each expressed as a comparison between a weighted sum of binary variables with integer values and an integer value, by deleting one of the plurality of constraints or deleting a number of binary variables used in any of the plurality of constraints.
